(19) United States
(12) Patent Application Publication
(10) Pub. No.: US 2008/0206973 A1
(43) Pub. Date: Aug. 28, 2008

(54) Process method to optimize fully silicided gate (FUSI) thru PAI implant

(75) Inventors: Frank Scott Johnson, Richardson, TX (US); Freidoon Mehrad, Plano, TX (US); Jiong-Ping Lu, Richardson, TX (US)

Correspondence Address: TEXAS INSTRUMENTS INCORPORATED, P O BOX 655474, M/S 3999, DALLAS, TX, 75265, US

(73) Assignee: Texas Instrument Inc.

(21) Appl. No.: 11/710,769

(22) Filed: Feb. 26, 2007

(51) Int. Cl. H01L 21/3205

(52) U.S. Cl. 438/585

(57) ABSTRACT

An improved method of forming a fully silicided (FUSI) gate in both NMOS and PMOS transistors of the same MOS device is disclosed. In one example, the method comprises forming oxide and nitride etch-stop layers over a top portion of the gates of the NMOS and PMOS transistors, forming a blocking layer over the etch-stop layer, planarizing the blocking layer down to the etch-stop layer over the gates, and removing a portion of the etch-stop layer overlying the gates. The method further includes implanting a preamorphizing species into the exposed gates to amorphize the gates, thereby permitting uniform silicide formation thereafter at substantially the same rates in the NMOS and PMOS transistors. The method may further comprise removing any remaining oxide or blocking layers, forming the gate silicide over the gates to form the FUSI gates, and forming source/drain silicide in moat areas of the NMOS and PMOS transistors.

### FIELD OF INVENTION

The present invention relates generally to semiconductor devices and more particularly to an innovative method of fabricating fully silicided metal gates (FUSI) in PMOS and NMOS transistor devices that provides a more uniform silicidation of the gates and more closely matched silicidation rates between the NMOS and PMOS transistor types of the same device.

### BACKGROUND OF THE INVENTION

It can be appreciated that several trends presently exist in the electronics industry. Devices are continually getting smaller, faster and requiring less power, while simultaneously being able to support and perform a greater number of increasingly complex and sophisticated functions. One reason for these trends is an ever increasing demand for small, portable and multifunctional electronic devices such as cellular phones, personal computing devices, and personal sound systems are devices which are in great demand in the consumer market.

Accordingly, there is a continuing trend in the semiconductor industry to manufacture integrated circuits (ICs) with higher device densities by scaling down dimensions (e.g., at submicron levels) on semiconductor wafers. To accomplish such high densities, smaller feature sizes, smaller separations between features and layers, and/or more precise feature shapes are required, such as metal interconnects or leads, for example. The scaling-down of integrated circuit dimensions can facilitate faster circuit performance and/or switching speeds, and can lead to higher effective yield in IC fabrication processes by providing or ‘packing’ more circuits on a semiconductor die and/or more die per semiconductor wafer, for example.

One way to increase packing densities is to decrease the thickness of transistor gate dielectrics to shrink the overall dimensions of transistors used in IC's and electronic devices. Transistor gate dielectrics (e.g., silicon dioxide or nitrided silicon dioxide) have recently been reduced considerably to reduce transistor sizes and facilitate improved performance. Thinning gate dielectrics can have certain drawbacks, however. For example, a polycrystalline silicon (“polysilicon”) gate overlies the thin gate dielectric, and polysilicon naturally includes a depletion region where it interfaces with the gate dielectric. This depletion region can provide an insulative effect rather than conductive behavior, which is desired of the polysilicon gate since the gate is to act as an electrode for the transistor.

By way of example, if the depletion region acts like a 0.8 nm thick insulator and the gate dielectric is 10-nm thick, then the depletion region effectively increases the overall insulation between the gate and an underlying transistor channel by eight percent (e.g., from 10 nm to 10.8 nm). It can be appreciated that as the thickness of gate dielectrics are reduced, the effect of the depletion region can have a greater impact on dielectric behavior. For example, if the thickness of the gate dielectric is reduced to 2 nm, the depletion region would effectively increase the gate insulator by about 40 percent (e.g., from 2 nm to 2.8 nm). This increased percentage significantly reduces the benefits otherwise provided by thinner gate dielectrics.

Metal gates can be used to mitigate adverse effects associated with the depletion region phenomenon because, unlike polysilicon, little to no depletion region manifests in metal. Interestingly enough, metal gates were commonly used prior to the more recent use of polysilicon gates. An inherent limitation of such metal gates, however, led to the use of polysilicon gates. In particular, the use of a single work function metal proved to be a limitation in high performance circuits that require dual work function electrodes for low power consumption. The work function is the energy required to move an electron from the Fermi level to the vacuum level. In modern CMOS circuits, for example, both p-channel MOS transistor devices (“PMOS”) and n-channel MOS transistor devices (“NMOS”) are generally required in the same device, where a PMOS transistor requires a work function on the order of 5 eV and an NMOS transistor requires a work function on the order of 4 eV. A single metal can not be used, however, to produce a metal gate that provides such different work functions. Polysilicon gates are suited for application in CMOS devices since some of the gates can be substitutionally doped in a first manner to achieve the desired work function for PMOS transistors and other gates can be substitutionally doped in a second manner to achieve the desired work function for NMOS transistors. However, polysilicon gates suffer from the aforementioned gate depletion.

Fully silicided (FUSI) gates eliminate the problem of polysilicon depletion. FUSI gates also reduce the gate conductance that can further improve device performance. A FUSI gate can be formed by depositing a metal layer (such as Ni, Ti, Co, Pt, etc.) over an exposed polysilicon gate region, pre-annealing to provide the required diffusion, removing the unreacted metal, and then annealing the semiconductor structure to form a more stable silicide alloy phase. The deposited metal reacts with the exposed polysilicon gate to transform the polysilicon gate fully into a silicided gate. FUSI gates normally have a work function near the middle of the silicon band structure. However, CMOS devices normally require a conductive gate with a work function near the band edge; i.e., near the conduction band for an NMOS device and near the valence band for a PMOS device, respectively. Thus, for CMOS technologies with FUSI gates, the different work functions required for each of the NMOS and PMOS portions of the CMOS device present a fabrication challenge as both types are usually required in the same device and may also require different dopant species in the doping process.

In addition, the suicide typically forms at different rates in the NMOS and PMOS devices to the point where it may be difficult to obtain a controllable or stable silicidation process. Because of these differing formation rates and the instability of the conventional process, the gate suicide formation occurring in a PMOS transistor may be yet incomplete, while an NMOS type transistor in the same device may have excessively formed and punched through the gate oxide layer.

Consequently, it would be desirable to be able to provide the uniform formation of a fully silicided gate in both NMOS and PMOS regions of a single MOS device.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

The present invention relates to an improved method of uniformly forming a fully silicided (FUSI) gate in both NMOS and PMOS transistor regions of the same MOS device. In one embodiment, source/drain (S/D) and gate structures of NMOS and/or PMOS transistors are provided in a device such as a semiconductor device. An etch-stop layer, for example, an oxide such as a pad oxide and a hardmask such as a nitride hardmask are formed over the device such as a top portion of the gates, and a blocking layer such as an oxide or TEOS (tetraethyl orthosilicate) are formed over the hardmask. The blocking layer (oxide or TEOS) is then planarized such as by a chemical mechanical polishing (CMP) process down to land on the hardmask over the NMOS and/or PMOS gate structures and the device is then post CMP cleaned. The hardmask is then etched such as by a dry etch to expose the top of the gate and then post etch cleaned.

The exposed polysilicon of the gates is then preamorphized using a preamorphization implant (PAI) (e.g., using a Si, Ge, In, Sb, C, N, an amorphizing element, and a combination of amorphizing elements) to amorphize the gate material creating a more homogenous gate material, for example, comprising random, uniformly distributed silicon atoms. The amorphous state of the silicon then also permits the uniform formation of a suicide in the gate, while permitting a more balanced work function between the NMOS and PMOS regions. Any remaining oxide barrier may then be removed from the top of the gate and the all the blocking layer (oxide or TEOS) from the top of the hardmask (e.g., nitride hardmask) on the moat, for example, using a hydrofluoric acid (HF) rinse, and a dry etch may be used thereafter to remove the nitride from the moat areas. Optionally thereafter, the gate may be silicided conventionally, to form the FUSI gate, and the remaining etch-stop such as an oxide and nitride may be removed from the moat area to allow formation of a subsequent source/drain silicide.

Thus, the method provides a more uniform FUSI gate formation in both NMOS and PMOS transistor regions of the same CMOS device. In addition, the method still permits the use of one or more metal species to be deposited, sputtered, or implanted, and one or more annealing operations per silicide formation. The PAI method of the present invention permits the NMOS and PMOS gate silicidations to be formed at much more balanced or comparable rates, adjustment and balancing of the work functions with the proper selection of dopants, and also provide the possibility of a blanket implant having self-alignment capability with the proper selection of dopants. In addition, the FUSI gates of the transistors allow device dimensions, such as gate dielectric thicknesses, for example, to be reduced to facilitate increased packing densities. Additionally, the transistors can be efficiently formed as part of a CMOS fabrication process.

In accordance with another aspect, the work functions of the NMOS and PMOS transistors are adjusted by the preamorphizing species and permits uniform silicide formation at substantially the same rates in the NMOS and PMOS transistors.

In accordance with another aspect, implanting the preamorphizing species comprises implanting different preamorphizing species into the NMOS and PMOS transistor gates.

In accordance with another aspect, the implanting of the preamorphizing species comprises implanting the same preamorphizing species into both the NMOS and PMOS transistor gates.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIGS. 1A-1C and 1E are fragmentary cross sectional diagrams illustrating some problems in the conventional formation of an exemplary FUSI gate transistor, and forming a silicide concurrently in both NMOS and PMOS transistors of the same device.

FIGS. 1D and 1F are fragmentary cross sectional diagrams illustrating one or more exemplary methodologies for forming an exemplary FUSI gate transistor in accordance with one or more aspects of the present invention.

FIGS. 2A, 2B and 2C are flow diagrams illustrating one or more exemplary methodologies for forming an exemplary FUSI gate transistor in both NMOS and PMOS transistors of a device according to one or more aspects of the present invention.

FIGS. 3A-3J are fragmentary cross sectional diagrams illustrating the formation of an exemplary FUSI gate transistor in both NMOS and PMOS transistors of a device according to one or more aspects of the present invention, such as by the methodologies set forth in FIGS. 2A, 2B and 2C.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. It will be appreciated that where like acts, events, elements, layers, structures, etc. are reproduced; subsequent (redundant) discussions of the same may be omitted for the sake of brevity. In the following description, for purposes of explanation, numerous specific details are set forth in order to provide a thorough understanding of one or more aspects of the present invention. It may be evident, however, to one of ordinary skill in the art that one or more aspects of the present invention may be practiced with a lesser degree of these specific details. In other instances, known structures are shown in diagrammatic form in order to facilitate describing one or more aspects of the present invention.

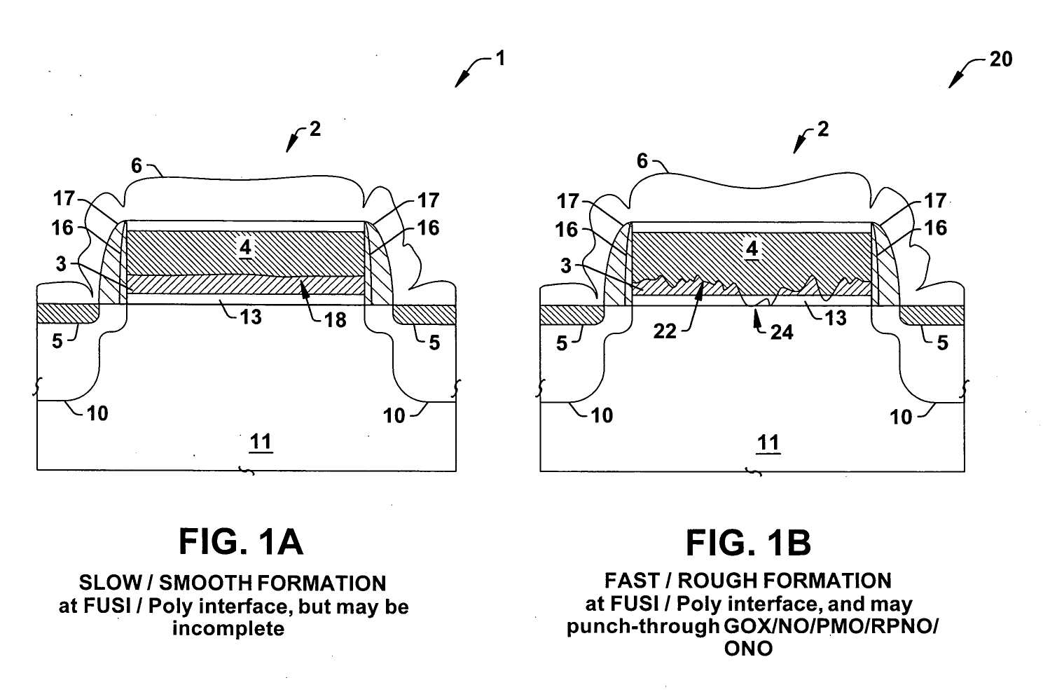

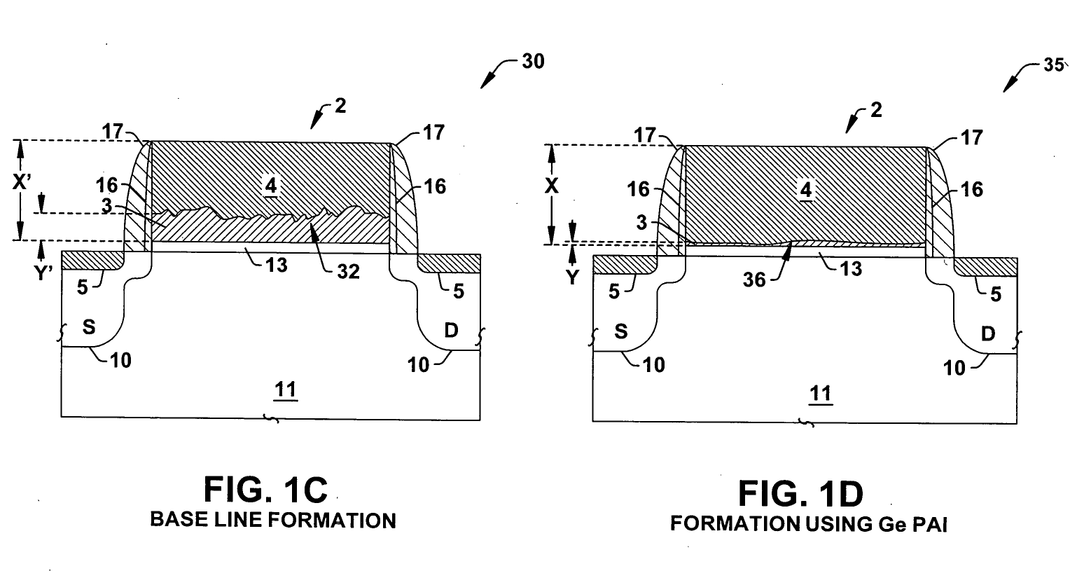

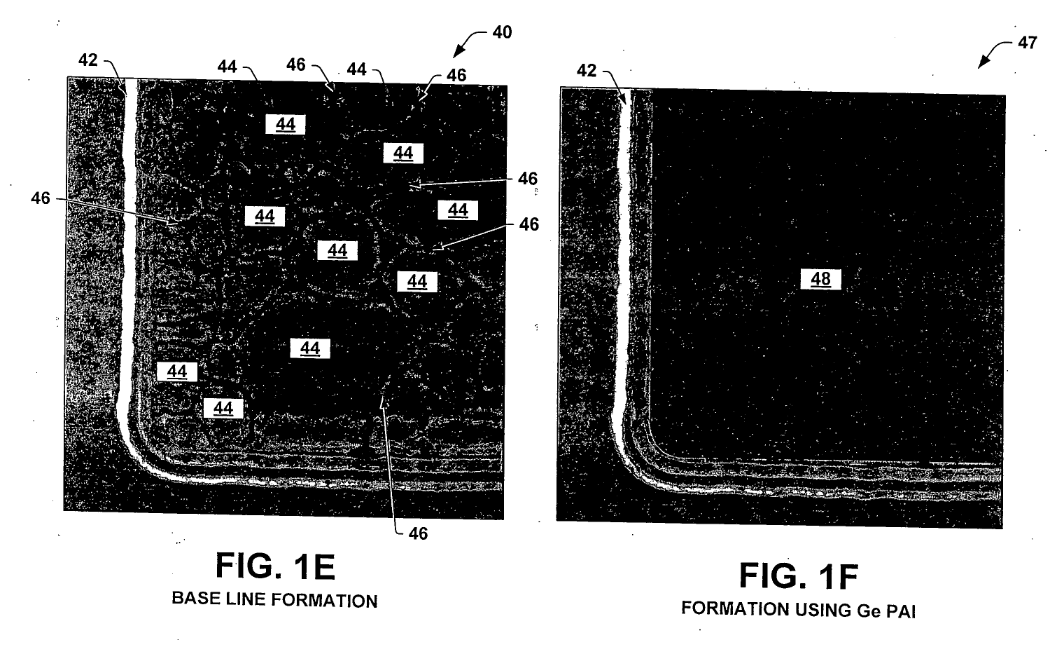

Turning to FIGS. 1A and 1B, a problem is illustrated in the conventional formation of an exemplary FUSI gate transistor 1 and 20 of PMOS and NMOS transistors, respectively, of the same device such as may be fabricated in accordance with one or more aspects of the method of the present invention. For example, transistors 1 and 20 of FIGS. 1A and 1B, respectively, comprise a fully silicided (FUSI) gate 2 formed over source/drain (S/D) regions 10 formed within a semiconductor substrate 11. Conventionally the FUSI gate 2 comprises a gate oxide (e.g., GOX, NO, PNO, RPNO, or ONO) 13 formed overlying the substrate 11. The FUSI gate 2 also comprises a silicon-containing gate material 3 such as a polysilicon gate material 3 which is silicided by the addition of a gate silicide metal such as Ni, Ti, Pt, and Co, for example, over the silicon-containing gate material 3, and forming a gate silicide 4 such as an NiSi alloy in a portion of the FUSI gate 2. The gate silicide metal may be added, for example, using a deposition, sputtering, or ion implantation process.

In a similar manner, an S/D silicide 5 is formed in the source/drain regions 10 by silicidation of the exposed polysilicon 11 using an S/D silicide metal. Offset spacers (OS) 16 and side-wall spacers (SWS) 17, initially used to implant dopants into the source/drain regions 10, may also be subsequently used to guide the formation of the S/D silicidation 5, for example, using a deposition, sputtering, or ion implantation process. The gate silicide metal and the S/D silicide metal may be the same or different metal or other dopant species.

FIGS. 1A and 1B also illustrates that a significant difference in the formation rates and formation characteristics between PMOS transistor 1 and NMOS transistor 20, particularly when these two types are formed concurrently in the same device. That is, the dopants in the polysilicon, for example, have a significant impact on the reaction rate of Ni with silicon. For example, in a PMOS transistor 1, a p-type dopant such as B may be used wherein the silicide reaction rate is slower, whereas in the NMOS transistor 20, an n-type dopant such as As, Sb, or P may be used, wherein the silicide reaction rate is fast. In addition, the PMOS reaction front 18 is smoother along with the slower formation, while the NMOS reaction front 22 is rougher along with the faster formation. The inventors of the present invention expect that a combination of the grain structure of the polysilicon combined with the segregation of the dopants at the grain boundaries is responsible for these non-uniform reaction rate effects.

These problems make it difficult to control the silicidation process for FUSI (fully silicided gate) and can result in NiSi punch-through 24 of the gate oxide 13, and incomplete polysilicon silicidation 32. Thus, the PAI implant method of the present invention provides a solution to these problems, providing a smoother FUSI/poly interface for more control of the gate poly silicidation. Also, with a smoother FUSI lower interface 18, there is less chance of the Ni diffusing through the gate oxide 13 or an incomplete FUSI formation of the polysilicon 3.

For example, FIGS. 1C and 1D contrast the difference between a conventionally formed FUSI gate 2 of a MOS transistor 30 of FIG. 1C, to that of a similar FUSI gate 2 of a MOS transistor 35 of FIG. 1D which has been formed using the preamorphization implant (PAI) method of the present invention. FIG. 1C, for example, illustrates a rough and incomplete FUSI interface 32 that has been conventionally formed, wherein the thickness Y′ of the unreacted polysilicon 3 is a significant proportion of the overall gate polysilicon height X′. By contrast, FIG. 1D illustrates a smoother and more complete FUSI interface 36 formed using the preamorphization implant of the present invention, wherein the thickness Y of the unreacted polysilicon 3 is a smaller or much less significant proportion of the overall gate polysilicon height X.

FIGS. 1E and 1F further contrast a conventionally formed polysilicon device 40 of FIG. 1E, and an amorphous polysilicon device 47 of FIG. 1F, wherein the polysilicon has been formed using the preamorphization implant (PAI) method of the present invention. FIG. 1E illustrates several problems of the conventionally formed polysilicon near a chip edge 42 of the polysilicon device 40, for example, an “alligator skin” effect is evident in the polysilicon, wherein the grain structures 44 are defined by heavy grain boundaries 46 surrounding each polysilicon grain structure 44. By contrast, the amorphized polysilicon device 47 of FIG. 1F illustrates that a homogenous or random uniformly distributed grain structure 48 has been formed without grain boundaries using the PAI implant method of the present invention.

As discussed above, the inventors of the present invention believe that a combination of the grain structure of the polysilicon combined with the segregation of the dopants at the grain boundaries is responsible for these non-uniform reaction rate effects. Therefore, the PAI implant, achieves a smoother and more uniform silicide formation rate between the NMOS and PMOS transistor types, for example, by removing the grain boundaries of the polysilicon before the FUSI silicide formation during the implantation of one or more amorphizing species such as Si, Ge, In, Sb, C, N, an amorphizing element, and a combination of amorphizing elements. It is also anticipated that the amorphizing element or elements will provide an appropriate work-function for both NMOS and PMOS devices prior to the Ni sputter of the silicide metal, for example. By amorphizing the top of the gate polysilicon prior to the Ni sputter, it then becomes easier for the Ni to form a uniform silicide.

In one embodiment of the present invention, an etch-stop layer such as an oxide and a nitride hardmask layer are formed over a top portion of the gates of an NMOS and PMOS transistor of a CMOS device. A blocking layer such as an oxide or TEOS layer is then formed over the etch-stop layer. A chemical-mechanical polishing (CMP) or another such planarization is then performed down to land on the nitride of the etch-stop layer and then the device is post CMP cleaned. A dry nitride etch is then used to expose the top of the gates and a post etch clean is performed. The exposed NMOS and PMOS gates are then amorphized using a preamorphization implant (PAI), for example, using a Ge, Si, In, Sb, or C amorphizing element in preparation for a subsequent fully silicided gate FUSI gate process. Subsequently, and optionally, any remaining oxide may be removed from the top of the gate poly and the TEOS from the top of the nitride on the moat areas, for example, using a hydrofluoric acid (HF) rinse, and a dry etch to remove the nitride from the moat areas prior to formation of an S/D silicide. Accordingly, the method of the present invention allows the gate silicide to be formed more uniformly in both NMOS and PMOS areas of the same device.

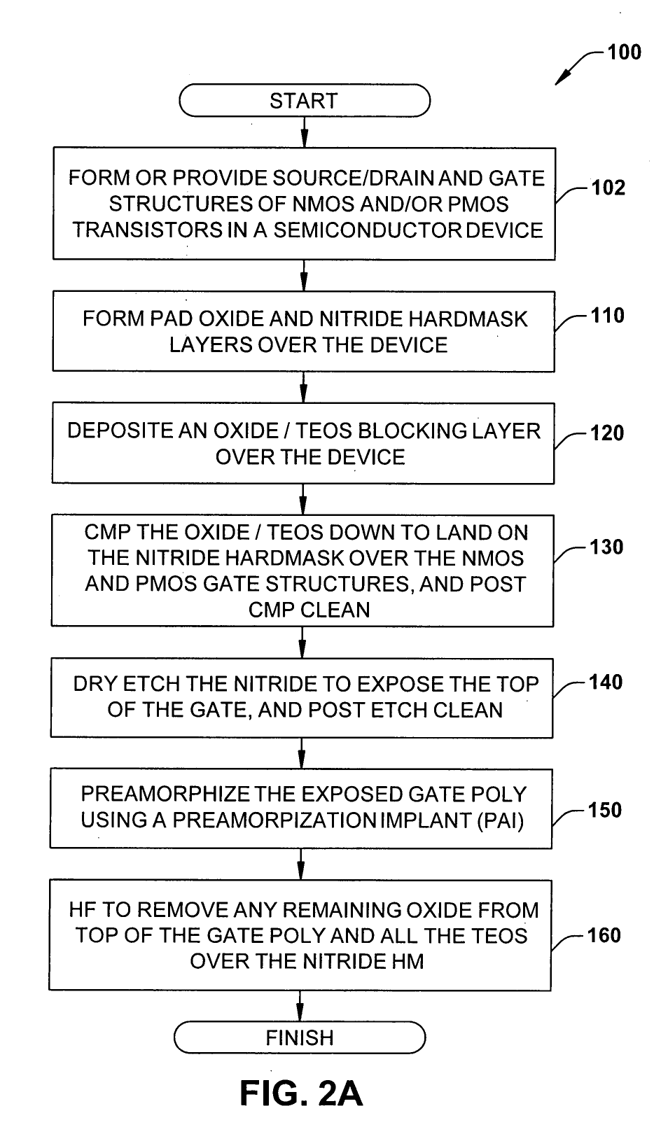

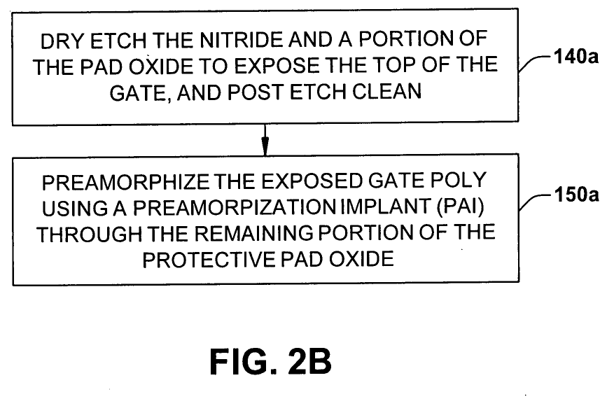

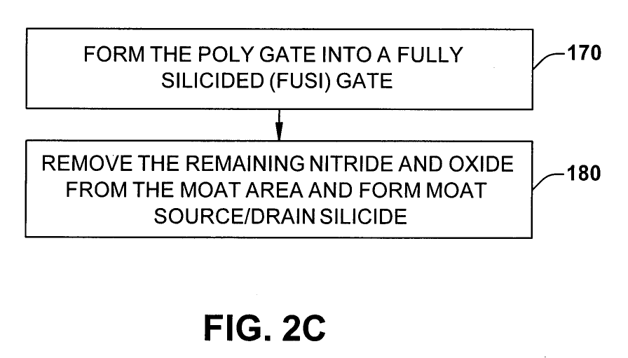

FIGS. 2A, 2B and 2C, for example, illustrate one or more exemplary methodologies for uniformly forming an exemplary FUSI gate in both NMOS and PMOS transistors of the same MOS device according to one or more aspects of the present invention.

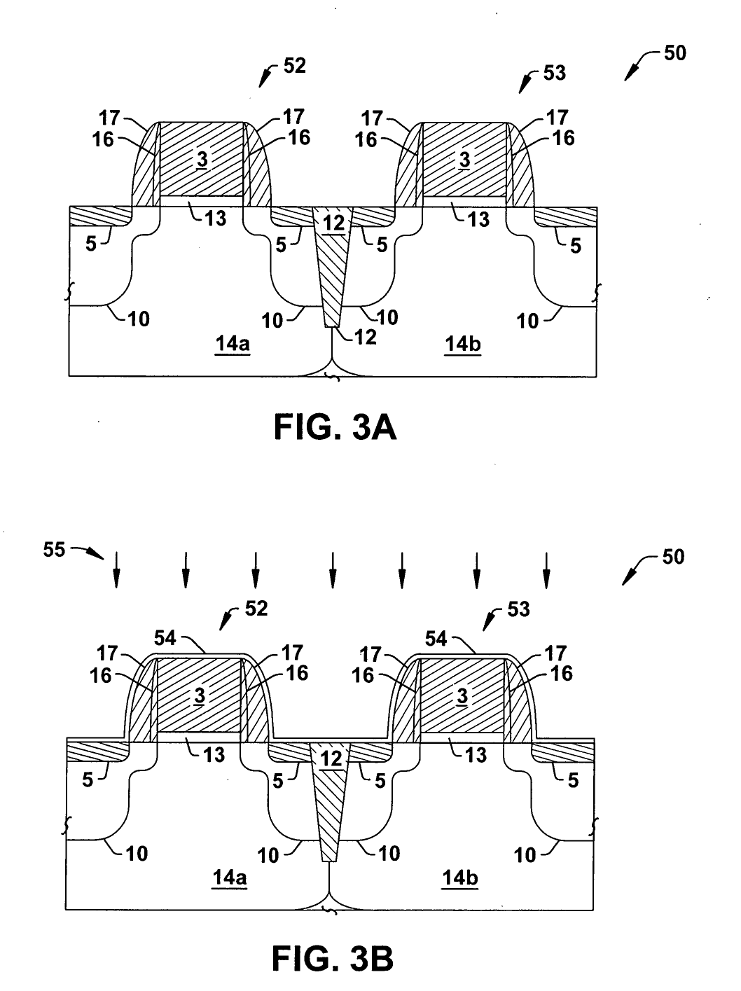

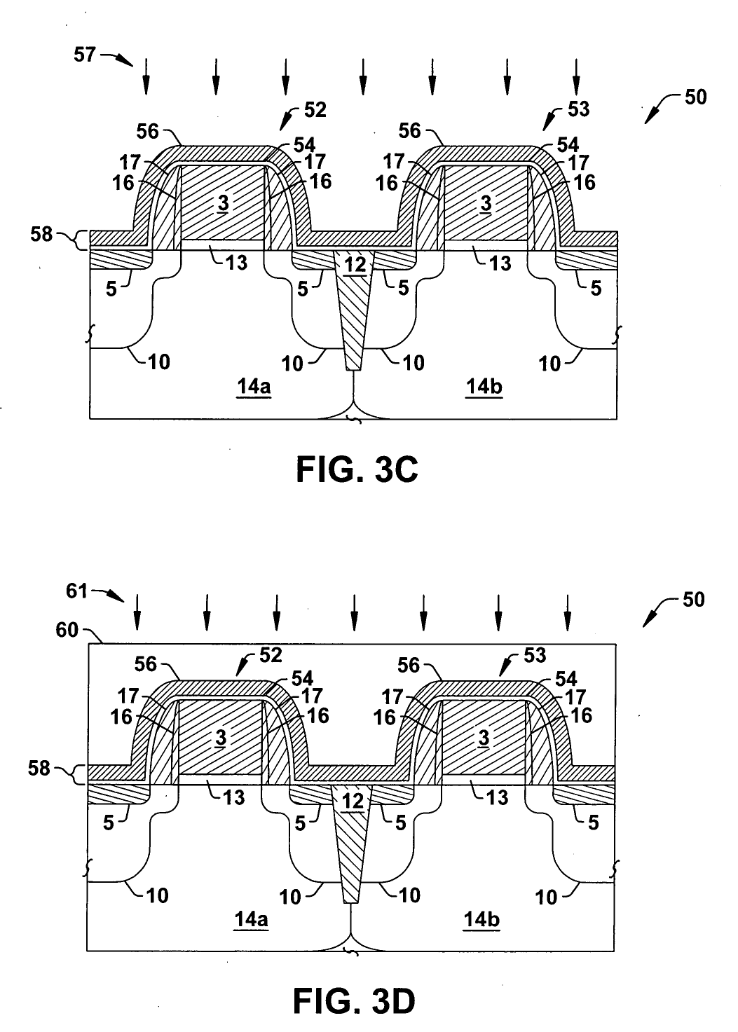

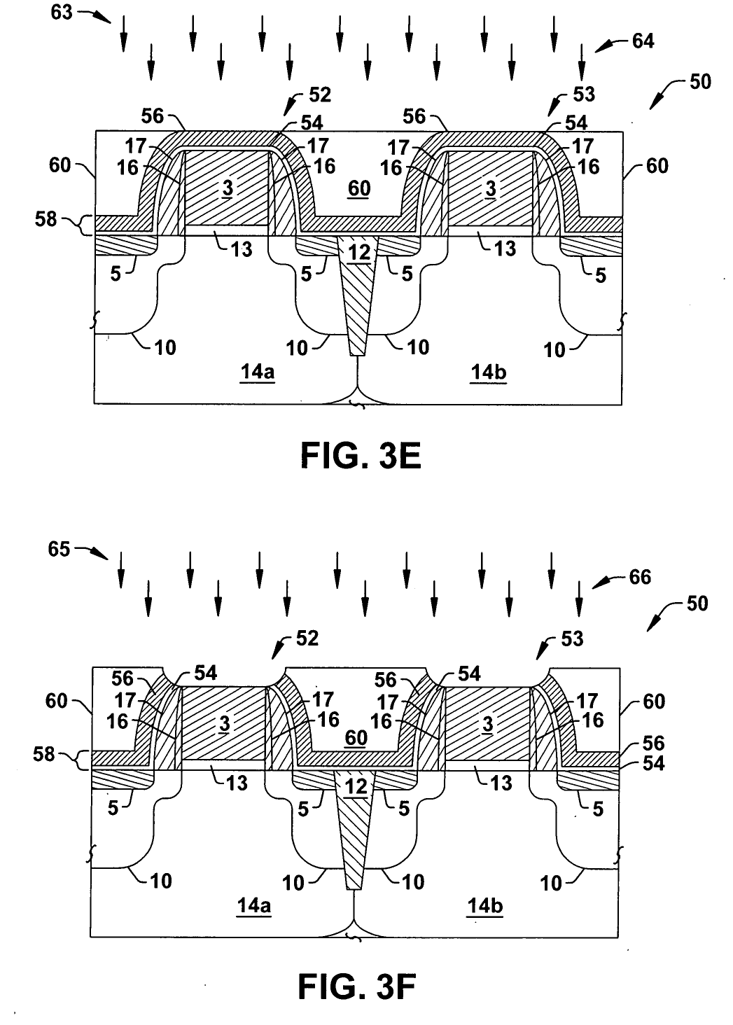

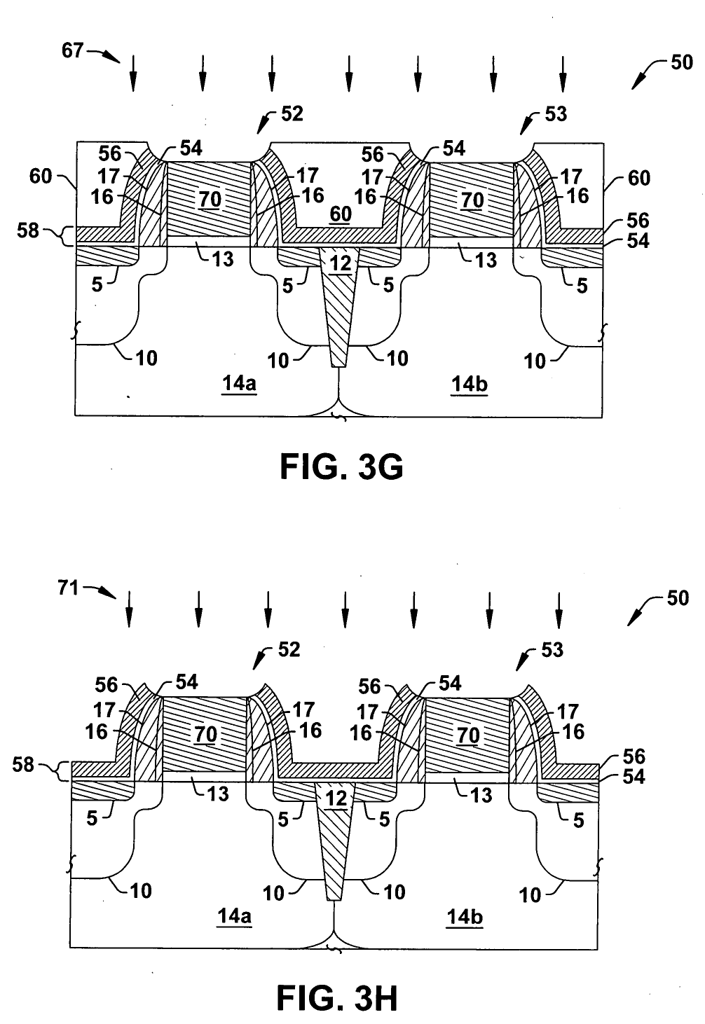

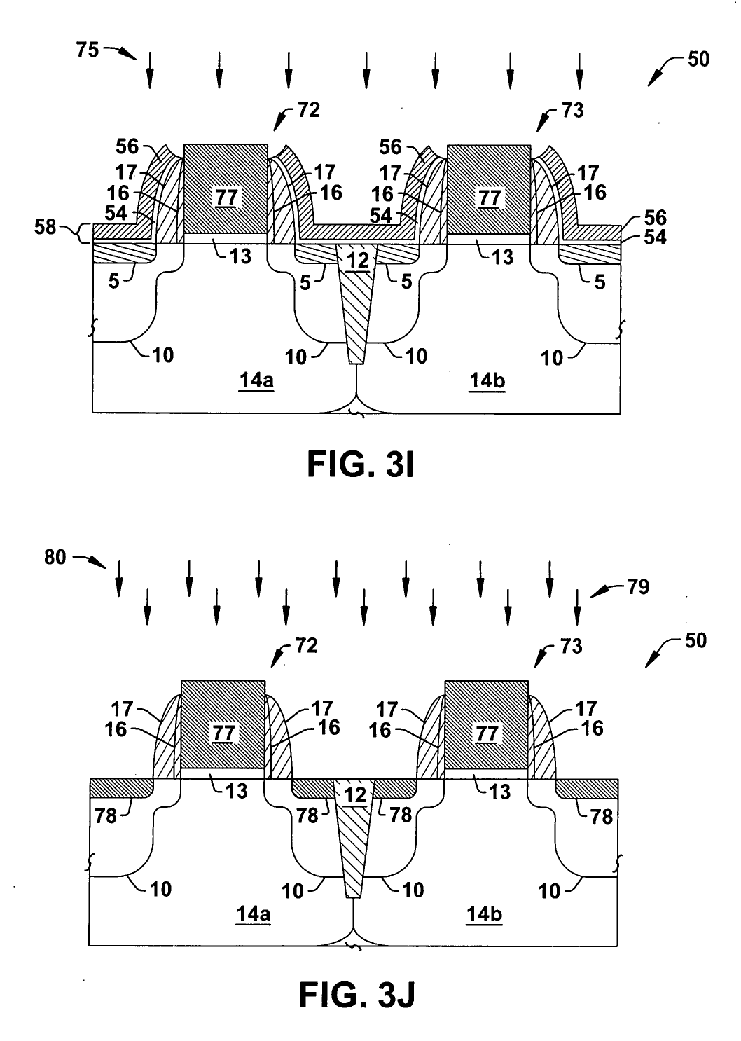

In FIG. 2A, an exemplary methodology 100 is illustrated for forming both NMOS 52 and PMOS 53 FUSI gate transistors according to one or more aspects of the present invention, for example, as in the fabrication steps of a MOS device 50 of FIGS. 3A-3J. As with all methodologies discussed herein, although the methodology 100 is illustrated and described hereinafter as a series of acts or events, it will be appreciated that the present invention is not limited by the illustrated ordering of such acts or events. For example, some acts may occur in different orders and/or concurrently with other acts or events apart from those illustrated and/or described herein. In addition, not all illustrated steps may be required to implement a methodology in accordance with one or more aspects of the present invention. Further, one or more of the acts may be carried out in one or more separate acts or phases. It will be appreciated that a methodology carried out according to one or more aspects of the present invention may be implemented in association with the formation and/or processing of structures illustrated and described herein as well as in association with other structures not illustrated or described herein.

The methodology 100 begins at 102, wherein an NMOS transistor 52 and a PMOS transistor 53 of a MOS device 50 is initially formed or otherwise provided (FIG. 3A), wherein the method will be carried-out. For example, in FIG. 3A, the NMOS transistor 52 is formed in a p-well 14a, while PMOS transistor 53 is formed in an n-well 14b, the p-well 14a separated from n-well 14b by a shallow trench isolation structure STI 12. NMOS transistor 52 and PMOS transistor 53 each comprise a source/drain regions 10 formed in the respective p-well 14a of the N-type transistor 52 or the n-well 14b of the P-type transistor 53. The gates of the transistors comprise a polysilicon gate material 3 overlying a gate oxide GOX 13, while offset spacers 16 and sidewall spacers 17 are formed on lateral sidewalls of the gate structures 52/53 for guiding the formation of the source/drain region structures 10 and other associated implantations, for example.

Then at 110, a thin oxide or pad oxide layer 54 (FIG. 3B) is formed 55 (e.g., by deposition or oxidation) over the NMOS transistor 52 and the PMOS transistor 53 of the single MOS device 50. Also at 110, a thin nitride or nitride hardmask layer 56 (FIG. 3C) is formed 57 (e.g., by a selective deposition of the nitride 56 of FIG. 3C) over the NMOS transistor 52 and the PMOS transistor 53 of the single MOS device 50. The pad oxide layer 54 and the nitride hardmask layer 56 also collectively form what may be known as a pre-metal dielectric (PMD) etch stop layer or simply an etch-stop layer 58 of FIG. 3C.

At 120, a blocking layer such as an oxide or TEOS blocking layer 60 of FIG. 3D is then formed 61 (e.g., by oxidation or deposition) over the etch-stop layer 58, for example, over the nitride hardmask layer 56 of the etch-stop layer 58 of FIG. 3D.

At 130, a planarization or chemical-mechanical polishing (CMP) 63 (FIG. 3E) is performed on the device 50, polishing 63 down to land on the nitride 56 of the etch-stop layer 58 over the gates of the NMOS and PMOS transistors 52/53, and then the device 50 is post CMP cleaned 64.

At 140, the top of the nitride 56 is then removed 65, for example, by a dry nitride etch 65 of FIG. 3F to expose the top of the gates 52/53 of the device 50, and a post etch clean 66 is performed.

It will be appreciated that the selective nature of the dry nitride etch 65 may be adjusted to remove various proportions of the nitride hardmask 56 and the pad oxide 54 and/or the TEOS blocking layer 60 to expose or protect a top portion of the gates 52/53 to a desired level, for example.

Accordingly, as at step 140a of FIG. 2B, the dry nitride etch 65 may be used to remove all of the nitride layer 56, but only to remove a portion of the pad oxide layer 54 so as to protect the top of the gate. Then the device 50 is post etch cleaned 66. Thus, a portion of the etch stop layer (oxide and nitride layers) may be removed, including any portion between 0-100% of the etch stop layer.

At 150, the exposed NMOS and PMOS polysilicon transistor gates 52 and 53, respectively, are then amorphized using a preamorphization implant (PAI) 67 of FIG. 3G, for example, using a Ge, Si, In, Sb, N, and C amorphizing element, or a combination of such amorphizing elements, in preparation for a subsequent FUSI gate silicidation process, wherein the polysilicon material 3 of the gates 52/53 is transformed into an amorphous silicon state 70 of FIG. 3G.

At alternate step 150a of FIG. 2B, if some of the pad oxide 54 is left overlying the gates to protect the polysilicon of the gates, as at alternate step 140a, the PAI implant 67 may also be implanted with enough energy to implant thru the remaining pad oxide layer 54, wherein the polysilicon material 3 of the gates 52/53 is likewise transformed into an amorphous silicon state 70 of FIG. 3G.

It will be appreciated in accordance with the present invention, that the gate structures of the NMOS and PMOS transistors 52/53 may be implanted concurrently with the same amorphizing species, or each transistor type (NMOS or PMOS) may be masked and implanted separately with differing species or combinations of species tailored to provide a desired work function for the respective transistor type.

Thereafter at 160, any remaining oxide 54 may be removed 71 (FIG. 3H) from the top of the gate poly and the TEOS 60 from the top of the nitride 56, for example, using a hydrofluoric acid (HF) rinse 71 prior to the formation of a gate silicide.

Optionally, thereafter at 170 of FIG. 2C, the polysilicon gates may be formed 75 of FIG. 3I into a fully silicided FUSI gate 77, for example, by depositing a gate metal over the polysilicon of the gates 72/73, preannealing, stripping the unreacted gate metal, and final annealing the device to reform the silicide alloy (e.g., an Ni₂Si alloy) into a more stable phase of the silicide alloy, for example, from an Ni₂Si alloy into a more stable NiSi alloy phase 77 of FIG. 3I.

Also optionally at 180 of FIG. 2C, the remaining nitride 56 and oxide 54 from the moat areas of the device 50 may be removed 79/80 as illustrated in FIG. 3J. For example, the nitride 56 may be removed 79 using a dry etch or wet etch such as with hot phosphoric acid, and the oxide 54 may be removed 80, thereafter, using a hydrofluoric acid (HF) rinse 80 prior to the formation of an S/D silicide 78 in the moat areas of the device 50.

Accordingly, the method of the present invention allows a gate silicide 77 to be formed more uniformly in both NMOS and PMOS transistors 72/73 of the same device 50, for example. In addition, because the amorphous nature of the silicon is more homogenous, forming without grain boundaries, the gate silicide may be formed with greater stability and more completely with less risk of gate oxide punch-through. In other words, the desired silicide thickness may be obtained in a more controlled manner using the method of the present invention, wherein the unreacted gate polysilicon Y is a smaller proportion of the total gate thickness X (FIG. 1D), where Y<<X.

It will be appreciated, in the context of the present invention that during the formation of the gate silicide, the gate silicide metal may be added to the amorphized gate polysilicon 70, such as by a deposition and/or implantation process 75, for example. The gate silicide metal reacts with the exposed gate polysilicon 70 in the gates 52/53 to form a more stable phase of silicide alloy, for example from a Ni₂Si alloy to a more stable NiSi silicide alloy 77 in the gates 72/73. The gate silicide metal is used to set or establish a particular work function in the gates 72/73. To establish a work function for a PMOS type transistor, for example, the gate silicide metal may comprise Co, Ni, Se, Rh, Pd, Te, Re, Ir, Pt and/or Au, for example, and may have a work function of between about 4.8 eV and about 6.0 eV, for example.

In another aspect of the present invention, the S/D and gate silicide metals may be formed from different species, the same species, or various combinations of metal species which provides the appropriate needed work functions. For example, a CoSi S/D silicide and a Ni gate silicide may be easily formed after using the PAI method of the present invention to provide a more uniform silicide formation.

Accordingly, one or more silicidation processes are performed at 170 wherein heat is applied (e.g., annealing) to form the fully silicided FUSI gates 72/73 (FIGS. 3I) of the MOS transistor 50. It will be appreciated that, as with all silicidation (e.g., heating, annealing) processes described herein, this process can be performed in an inert ambient at a temperature of between about 300 and about 1000 degrees Celsius for between about 10 seconds to about 5 minutes, for example. Additionally, the resulting alloy may have a thickness of about 100 nanometers or less, for example.

It will be appreciated that, according to one or more aspects of the present invention, the S/D silicide metal and gate silicide metal form stable alloys within the respective polysilicon areas during the silicidation process, for example, for forming one or more NMOS or PMOS type transistors 50.

Although not illustrated, it will be appreciated that other aspects of the transistor fabrication can also be done after gate structures are provided or before the silicidation process is performed. These include doping the substrate to establish source and drain regions therein adjacent to the gate structures, thereby establishing respective channel regions under the gate structures between the source and drain regions, LDD, MDD, or other extension implants, appropriate dopant activation anneals for source-drain, LDD and MDD dopants, and left and right sidewall spacer formation along left and right lateral sidewalls of the respective gate structures. Further metallization, and/or other back-end processing can also be subsequently performed.

Additionally, it will also be appreciated that the polysilicon, as well as the gate dielectric material 13 can be patterned before the metals are provided and the silicidation process is performed. In this scenario, selective masking/patterning may need to be implemented to inhibit these, as well as other materials from being imparted into exposed source/drain regions 10 of either the p-well 14a of N-type gate 52 or the n-well of P-type gate 53, for example.

Further, forming FUSI gate transistors as described herein can be implemented in a CMOS fabrication process in an efficient and cost effective manner.

Accordingly, forming transistors according to one or more aspects of the present invention allows different types of FUSI gate transistors having different respective work functions to be concurrently formed in a single fabrication process. Forming the different types of transistors allows their respective advantages to be taken advantage of to satisfy different circuit application requirements. The FUSI gate transistors also allow feature sizes, such as dielectric thicknesses, for example, to be reduced to facilitate device scaling and increase packing densities.

It will be appreciated that while reference is made throughout this document to exemplary structures in discussing aspects of methodologies described herein (e.g., those structures presented in FIGS. 3A-3J while discussing the methodology set forth in FIGS. 2A, 2B and 2C, that those methodologies are not to be limited by the corresponding structures presented. Rather, the methodologies (and structures) are to be considered independent of one another and able to stand alone and be practiced without regard to any of the particular aspects depicted in the figures.

It is also to be appreciated that layers and/or elements depicted herein are illustrated with particular dimensions relative to one another (e.g., layer to layer dimensions and/or orientations) for purposes of simplicity and ease of understanding and that actual dimensions of the elements may differ substantially from that illustrated herein. Additionally, unless stated otherwise and/or specified to the contrary, any one or more of the layers set forth herein can be formed in any number of suitable ways, such as with spin-on techniques, sputtering techniques (e.g., magnetron and/or ion beam sputtering), (thermal) growth techniques and/or deposition techniques such as chemical vapor deposition (CVD), physical vapor deposition (PVD) and/or plasma enhanced chemical vapor deposition (PECVD), or atomic layer deposition (ALD), for example, and can be patterned in any suitable manner (unless specifically indicated otherwise), such as via etching and/or lithographic techniques, for example. Further, the term “exemplary” as used herein merely meant to mean an example, rather than the best.

Although one or more aspects of the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and/or advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A method of forming a FUSI gate concurrently in both NMOS and PMOS devices, comprising:
amorphizing at least a top portion of a gate electrode of both the NMOS and PMOS devices;
forming a FUSI gate suicide of the gate electrodes, wherein the amorphized gates permit uniform suicide formation at substantially the same rates in the NMOS and PMOS devices.

2. The method of claim 1, wherein amorphizing at least the top portion of the gate electrode of both the NMOS and PMOS devices comprises implanting different preamorphizing species into the NMOS and PMOS gates, and wherein at least one of the preamorphizing species comprises at least one of Si, Ge, In, Sb, C, N, an amorphizing element, and a combination of amorphizing elements.

3. The method of claim 2, wherein the work functions of the NMOS and PMOS devices are adjusted by the preamorphizing species and permits uniform silicide formation at substantially the same rates in the NMOS and PMOS devices.

4. The method of claim 1, wherein amorphizing at least the top portion of the gate electrode of both the NMOS and PMOS devices comprises implanting the same preamorphizing species into both the NMOS and PMOS gates, and wherein the preamorphizing species comprises at least one of Si, Ge, In, Sb, C, N, an amorphizing element, and a combination of amorphizing elements.

5. The method of claim 4, wherein the work functions of the NMOS and PMOS devices are adjusted by the preamorphizing species and permits uniform suicide formation at substantially the same rates in the NMOS and PMOS devices.

6. The method of claim 4, wherein the preamorphizing species is implanted concurrently into the NMOS and PMOS devices.

7. The method of claim 4, wherein the preamorphizing species is implanted separately into the NMOS and PMOS devices.

8. The method of claim 1, wherein the formation of the FUSI gate suicide of the gates comprises:
depositing a gate silicide metal over the gates;
first annealing the gates;
selectively removing any unreacted gate silicide metal from the transistors; and
second annealing to form the FUSI gate in both the NMOS and PMOS devices.

9. The method of claim 1, wherein the gate silicide is formed using a gate silicide metal, comprising:
Ni and at least one of Co, Sc, Y, La, Yb, Er, Cs, Ba, Ti, V, Fe, Nb, Cd, Sn, Hf, Ta, Zr, Be, Se, Rh, Pd, Te, Ru, Re, Ir, Pt and/or Au.

10. The method of claim 1, wherein the gate silicide is formed using a gate silicide metal added to the gates by at least one of a deposition, a sputter, and an implantation process.

11. The method of claim 1, wherein the gate silicide is formed using a gate silicide metal deposition comprising two or more metal depositions.

12. A method of forming a fully silicided (FUSI) gate concurrently in both NMOS and PMOS transistors of the same MOS device, comprising:
a) forming an etch-stop layer over the gates of the NMOS and PMOS transistors;
b) forming a blocking layer over the etch-stop layer;
c) planarizing the blocking layer down to the etch-stop layer over the gates;
d) removing at least a portion of the etch-stop layer from a top portion of the gates; and
e) implanting a preamorphizing species into the exposed gates to amorphize the gates, wherein the amorphized gates permit uniform silicide formation at substantially the same rates in the NMOS and PMOS transistors.

13. The method of claim 12, further comprising
f) removing any remaining etch-stop from the top portion of the gates, and removing the blocking layer from over the etch-stop.

14. The method of claim 13, wherein the removing of the remaining etch-stop and blocking layer comprises a hydrogen fluoride treatment of the device.

15. The method of claim 14, further comprising
g) forming a gate silicide over the gates comprising silicon-containing gates, thereby forming a FUSI gate in the transistors.

16. The method of claim 15, further comprising
h) removing the remaining etch-stop from moat areas of the NMOS and PMOS transistors; and
i) forming a source/drain silicide in the moat areas of the NMOS and PMOS transistors.

17. The method of claim 12, wherein the etch-stop comprises an oxide and a nitride layer.

18. The method of claim 12, wherein the etch-stop comprises one of an oxide, a pad oxide, and a dielectric layer, and further comprises one of a nitride, a nitride hardmask, and a hardmask layer over the gates of the NMOS and PMOS transistors.

19. The method of claim 12, wherein the removing the etch-stop layer from the gates comprises dry etching a nitride layer and a portion of an oxide layer to expose the top of the gates.

20. The method of claim 12, further comprising
post-etch cleaning the device after removing the etch-stop layer from the gates.

21. The method of claim 12, wherein the blocking layer comprises one of an oxide layer or a tetraethyl orthosilicate layer formed over the etch-stop layer.

22. The method of claim 12, wherein implanting the preamorphizing species comprises implanting different preamorphizing species into the NMOS and PMOS transistor gates, and wherein at least one of the preamorphizing species comprises at least one of Si, Ge, In, Sb, C, N, an amorphizing element, and a combination of amorphizing elements.

23. The method of claim 22, wherein the work functions of the NMOS and PMOS transistors are adjusted by the preamorphizing species and permits uniform silicide formation at substantially the same rates in the NMOS and PMOS transistors.

24. The method of claim 12, wherein implanting the preamorphizing species comprises implanting the same preamorphizing species into both the NMOS and PMOS transistor gates, and wherein the preamorphizing species comprises at least one of Si, Ge, In, Sb, C, N, an amorphizing element, and a combination of amorphizing elements.

25. The method of claim 24, wherein the work functions of the NMOS and PMOS transistors are adjusted by the preamorphizing species and permits uniform silicide formation at substantially the same rates in the NMOS and PMOS transistors.

26. The method of claim 15, wherein the formation of the gate silicide over the gates comprises:
depositing a gate silicide metal over the gates;
first annealing the gates;
selectively removing any unreacted gate silicide metal from the transistors; and
second annealing to form the FUSI gate in the MOS transistors.

27. The method of claim 15, wherein the gate silicide is formed using a gate suicide metal, and wherein at least one of the gate silicide metals of the NMOS and PMOS transistors comprises:
Ni, and at least one of Sc, Y, La, Yb, Er, Cs, Ba, Ti, V, Fe, Nb, Cd, Sn, Hf, Ta, and Zr, and has a work function of between about 3.0 eV and about 4.3 eV; and
the other of the gate silicide metals of the NMOS and PMOS transistors comprises at least one of Be, Co, Ni, Se, Rh, Pd, Te, Ru, Re, Ir, Pt and/or Au, and has a work function of between about 4.8 eV and about 6.0 eV.

28. The method of claim 15, wherein the gate silicide is formed using a gate silicide metal added to the gates by at least one of a deposition, a sputter, and an implantation process.

29. The method of claim 15, wherein the gate silicide is formed using a gate silicide metal deposition comprising two or more metal depositions.

30. The method of claim 12, wherein the planarizing the blocking layer down to the etch-stop layer over the gates is accomplished by a chemical mechanical polishing process.

31. A method of forming a fully silicided (FUSI) gate in both NMOS and PMOS transistors of the same MOS device, comprising:
a) forming an oxide layer and a nitride layer over a top portion of the gates of the NMOS and PMOS transistors;
b) forming an oxide blocking layer over the oxide and a nitride layers;
c) chemical mechanical polishing the oxide blocking layer down to the nitride layer over the gates;
d) removing the nitride layer and a portion of the oxide layer overlying the gates to expose the top of the gates after the chemical mechanical polishing; and
e) implanting a preamorphizing species into the exposed gates to amorphize the gates, wherein the amorphized gates permit uniform silicide formation at substantially the same rates in the NMOS and PMOS transistors.

32. The method of claim 31, further comprising
f) removing any remaining oxide from the top of the gates after the preamorphizing implant, and removing the oxide blocking layer from over the nitride layer;
g) forming a gate silicide over the gates to form a fully silicided (FUSI) gate in the transistors;
h) removing the remaining oxide and nitride from moat areas of the NMOS and PMOS transistors; and
i) forming a source/drain silicide in the moat areas of the NMOS and PMOS transistors.

33. The method of claim 32, wherein the removing of the remaining oxide or oxide blocking layer comprises utilizing a hydrogen fluoride treatment of the device.

34. The method of claim 31, wherein the removing the oxide and nitride layers from the gates comprises dry etching a nitride layer and a portion of an oxide layer to expose the top of the gates.

35. The method of claim 31, further comprising
post-etch cleaning the device after removing the oxide and nitride layers from the gates.

36. The method of claim 31, wherein the blocking layer comprises one of an oxide layer or a tetraethyl orthosilicate layer formed over the oxide and nitride layers.

37. The method of claim 31, wherein implanting the preamorphizing species comprises implanting different preamorphizing species into the NMOS and PMOS transistor gates, and wherein at least one of the preamorphizing species comprises at least one of Si, Ge, In, Sb, C, N, an amorphizing element, and a combination of amorphizing elements.

38. The method of claim 37, wherein the work functions of the NMOS and PMOS transistors are adjusted by the preamorphizing species and permits uniform silicide formation at substantially the same rates in the NMOS and PMOS transistors.

39. The method of claim 31, wherein implanting the preamorphizing species comprises implanting the same preamorphizing species into both the NMOS and PMOS transistor gates, and wherein the preamorphizing species comprises at least one of Si, Ge, In, Sb, C, N, an amorphizing element, and a combination of amorphizing elements.

40. The method of claim 39, wherein the work functions of the NMOS and PMOS transistors are adjusted by the preamorphizing species and permits uniform silicide formation at substantially the same rates in the NMOS and PMOS transistors.

41. The method of claim 32, wherein at least one of the NMOS and PMOS FUSI gates comprise at least one of
a work function of about 4 eV, and
a work function of about 5 eV.
